(19) United States
(12) Patent Application Publication
(10) Pub. No.: US 2026/0128733 A1
(43) Pub. Date: May 7, 2026

(54) ULTRA LOW POWER CLOCK BUFFER

(71) Applicant: STMicroelectronics International N.V., Geneva (CH)

(72) Inventors: Sahil Kumar JHA, New Delhi (IN); Prashutosh GUPTA, Greater Noida (IN); Nitin JAIN, Greater Noida (IN); Akshat KUMAR, Greater Noida (IN)

(73) Assignee: STMicroelectronics International N.V., Geneva (CH)

(21) Appl. No.: 19/378,828

(22) Filed: Nov. 4, 2025

Related U.S. Application Data
(60) Provisional application No. 63/716,820, filed on Nov. 6, 2024.

(51) Int. Cl. H03K 3/356; H03K 3/012

(52) U.S. Cl. CPC H03K 3/35606; H03K 3/012

(57) ABSTRACT

A low-power clock buffer circuit is disclosed that reduces crowbar current and improves power efficiency across a wide range of supply voltages. The circuit comprises an input stage with current-limited PMOS and NMOS transistors, and an output inverter stage with split-gate drive. The input stage uses current sources to control the rise and fall times of signals driving the output inverter, creating a delay between the activation of the PMOS and NMOS transistors in the output stage. This delay minimizes the duration when both output transistors are simultaneously conducting, significantly reducing crowbar current. An alternative embodiment includes a current-starved latch in the output stage to mitigate floating node situations and enhance signal integrity. The circuit is suitable for clock distribution networks in large digital systems.

### RELATED APPLICATION

This application claims priority to U.S. Application for Patent No. 63/716,820, filed Nov. 6, 2024, the content of which is incorporated by reference in its entirety.

### TECHNICAL FIELD

This disclosure relates to low-power clock buffer circuits for use in integrated circuits and System-on-Chip (SoC) designs.

### BACKGROUND

Clock buffers are used in modern integrated circuits, particularly in System-on-Chip (SoC) designs, where they are used to improve clock signal integrity as the clock signal traverses the chip. However, these clock buffers face a challenge in the form of high crowbar currents, especially when the input clock signals have poor rise and fall times. This issue directly impacts the power consumption of these buffers, which is a concern in power-sensitive applications.

The problem arises from the nature of CMOS inverters which form the basis of many clock buffer designs. In a CMOS inverter, an example of which is illustrated in FIG. 1A, there exists a brief time interval during input transitions when both the PMOS transistor MP1 and NMOS transistor MN1 are simultaneously conducting. This creates a direct path from the supply voltage VDD node to ground, resulting in what is known as crowbar current or short-circuit current, as indicated by the arrow in FIG. 1A.

The duration of this crowbar current becomes particularly problematic when the input signal has slow rise and fall times. As shown in the timing diagram in FIG. 1B, a slow transition at the input IN1 of the CMOS inverter prolongs the period during which both transistors MP1 and MN1 are on, leading to increased power consumption. This issue is exacerbated as the supply voltage VDD increases, making it a significant concern for circuits that need to operate across a wide voltage range.

Previous attempts to address this issue have included techniques such as the split-inverter approach, illustrated in FIG. 2. This method uses separate inputs INP and INN for the PMOS transistor M1 and NMOS transistor M2 forming the CMOS inverter of interest. Additional transistors M3, M4 & M5 are used to generate INP & INN. Transistor M3 is used to create a DC shift between INP and INN. While this can be effective in reducing short-circuit current, it introduces complexity and may struggle to maintain performance across a wide voltage range.

Another attempt, shown in FIG. 3, utilizes a current starving technique. This technique uses DC current sources I1 and I2 to limit the maximum short-circuit current flowing through the inverter formed by transistors M1 and M2. The input stage, formed by transistors M3 and M5, drives the main inverter. A load capacitance CLOAD is shown at the output OUT1. However, this approach can degrade the rise and fall times at the IN2 node if the current limits I1 and I2 are set too low, potentially shifting the problem to subsequent stages in the circuit. Here also, the optimized solution at a particular supply voltage fails to work efficiently across the wide supply voltage range.

These limitations in existing designs highlight the need for a more effective approach to designing ultra-low power clock buffers. As such, further development is needed.

### SUMMARY

According to one or more embodiments as described herein, such a result can be achieved via the features set forth in the claims that follow.

Embodiments as described herein can also relate to a corresponding system/method.

The claims are an integral part of the technical teaching provided herein in respect of the embodiments.

A low-power clock buffer circuit includes an input stage and an output stage. The input stage has a first PMOS transistor and a first NMOS transistor, each having a gate connected to receive an input signal. A first current source is connected to a drain of the first PMOS transistor. A second current source is connected to a drain of the first NMOS transistor. The output stage has a second PMOS transistor having a gate connected to the drain of the first PMOS transistor. A second NMOS transistor has a gate connected to the drain of the first NMOS transistor. The first and second current sources control timing of signals applied to the gates of the second PMOS and second NMOS transistors to reduce crowbar current in the output stage.

The circuit may have an output buffer connected to drains of the second PMOS and second NMOS transistors.

The circuit may have a current-starved inverter connected in a feedback configuration with the output buffer to form a latch.

The first current source may be connected between the drain of the first PMOS transistor and ground, and the second current source may be connected between a supply voltage and the drain of the first NMOS transistor.

The first and second current sources may control rise and fall times of signals at the drains of the first PMOS and first NMOS transistors, respectively.

The input stage and output stage may collectively form a low-power inverter with reduced crowbar current.

The circuit may be configured to operate efficiently across a range of supply voltages in a clock distribution network of a digital system.

A low-power clock buffer circuit includes a first push-pull stage and a second push-pull stage. The first push-pull stage has a first PMOS transistor and a first NMOS transistor, each having a gate connected to receive a respective input signal, wherein drains of the first PMOS transistor and the first NMOS transistor are connected to form a first output node. The second push-pull stage has a second PMOS transistor and a second NMOS transistor, each having a gate connected to receive the respective input signal, wherein drains of the second PMOS transistor and the second NMOS transistor are connected to form a second output node. An output stage has a third PMOS transistor having a gate connected to the second output node. A third NMOS transistor has a gate connected to the first output node. The first NMOS transistor and the second PMOS transistor are configured to be stronger than the first PMOS transistor and the second NMOS transistor, respectively, to control timing of signals at the first and second output nodes applied to the gates of the third PMOS and third NMOS transistors to reduce crowbar current in the output stage.

The respective input signals for the first and second push-pull stages may be level-shifted versions of a common input signal.

The circuit may have an output buffer connected to drains of the third PMOS and third NMOS transistors.

The circuit may have a current-starved inverter connected in a feedback configuration with the output buffer to form a latch.

The first and second push-pull stages may control rise and fall times of signals at the first and second output nodes, respectively.

The signals at the first and second output nodes may cause non-overlapping transitions in the third PMOS transistor and the third NMOS transistor.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1A illustrates a prior art CMOS inverter circuit.

FIG. 1B shows a timing diagram depicting the crowbar current issue in the prior art CMOS inverter.

FIG. 2 is a schematic diagram of a prior art split-inverter technique for reducing short-circuit current.

FIG. 3 is a schematic diagram of a prior art current-starving technique for limiting short-circuit current in an inverter.

FIG. 4 is a schematic diagram of a low-power clock buffer circuit according to an embodiment.

FIG. 5 is a timing diagram illustrating the operation of the circuit shown in FIG. 4.

FIG. 6 is a schematic diagram of an alternative embodiment of the low-power clock buffer circuit, incorporating a current-starved latch in the output stage.

FIG. 7 is a schematic diagram of a further embodiment of a low-power clock buffer circuit, also incorporating a current-starved latch in the output stage.

FIG. 8 shows a timing diagram illustrating the operation of the circuit shown in FIG. 7.

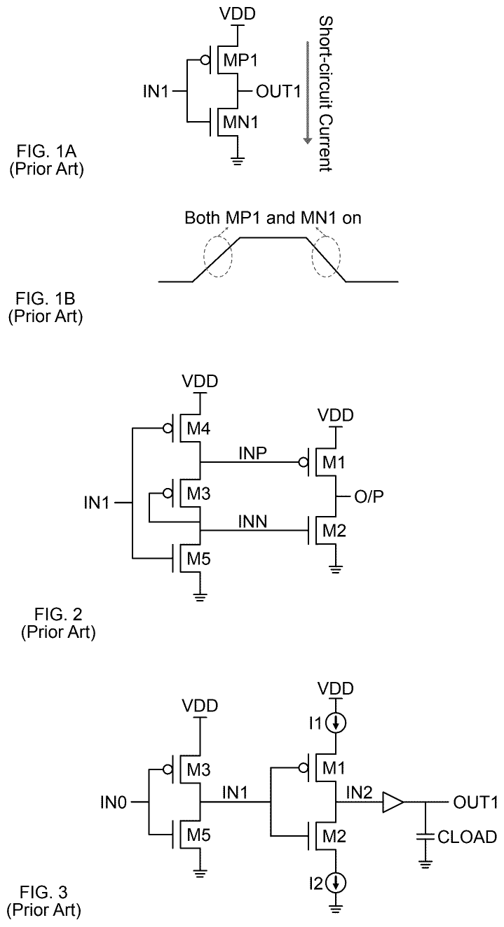

In order to favor the clarity of the features shown, the figures may be drawn in simplified fashion, are not necessarily drawn to scale, and the edges of the figures may not necessarily indicate termination of the extent of the feature.

### DETAILED DESCRIPTION

In the figures and in the rest of the description, like features have been designated by like references in the various figures; as such, a corresponding description may not be repeated for the sake of brevity. In particular, the structural and/or functional features that are common amongst the various embodiments may have the same references and may have identical structural, dimensional, and material properties. Finally, the different embodiments and variants are not exclusive to one another and can be combined amongst themselves.

The references used herein are provided merely for convenience and hence do not define the extent of protection or the scope of the embodiments.

In the ensuing description, one or more specific details are illustrated, aimed at providing an in-depth understanding of embodiments of this invention. The embodiments may be implemented without one or more of the specific details, or with other methods, components, materials, etc. In some cases, known structures, materials, or operations may not be illustrated or described in detail so as to not lose focus on the main aspects of embodiments of the invention.

Reference to “an embodiment” or “one embodiment” in the present description should be understood as meaning “at least one embodiment”. Moreover, phrases such as “in an embodiment” or “in one embodiment” that may be present in one or more points of the present description do not necessarily refer to one and the same embodiment. Moreover, particular configurations, structures, or characteristics may be combined in any manner known to skilled persons in one or more other embodiments.

Unless indicated otherwise, when reference is made to two elements directly connected together, this signifies direct contact of one element to the other without any intermediate elements. When reference is made to two elements connected or coupled together, this signifies that these two elements can be either directly connected or they can be indirectly connected via one or more other intermediate elements.

Unless specified otherwise, the expressions “about”, “around”, “approximately”, “substantially” and “in the order of” signify within 10 % or 10°, and preferably within 5 % or 5°. Additionally, the phrase “comprised between . . . and . . . ” or equivalent signifies that the end points are included, unless otherwise indicated.

Where not otherwise defined, all technical and scientific terms used herein have the same meaning commonly used by skilled persons in the field pertaining to the present invention. The views included in the attached figures and described herein are not intended as representations of structural features, i.e., constructional limitations, but should be interpreted as representations of functional features, i.e., functions that can be implemented in different ways.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

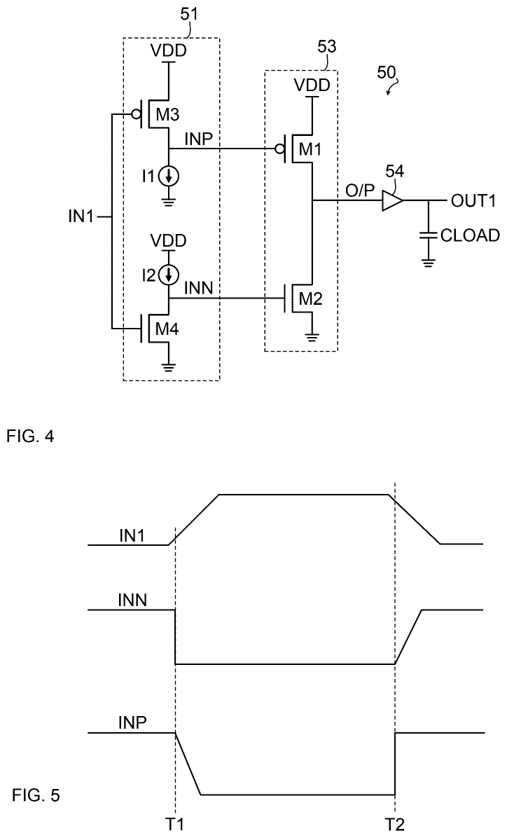

Referring now to FIG. 4, an embodiment of a clock buffer circuit 50 is illustrated. The circuit 50 comprises an input stage 51 and an output stage 53, collectively forming a low-power inverter with reduced crowbar current.

The input stage 51 includes a first PMOS transistor M3 and a first NMOS transistor M4. The source of transistor M3 is connected to a supply voltage VDD node, while its drain is connected to a first current source I1 (acting as a sink). The source of transistor M4 is connected to ground, and its drain is connected to a second current source I2 (acting as a source). The gates of both transistors M3 and M4 are connected to one another and receive an input signal IN1.

The first current source I1 is connected between the drain of transistor M3 and ground, while the second current source I2 is connected between the supply voltage node VDD and the drain of transistor M4. These current sources I1 and I2 serve to limit the current flow through their respective branches, thereby controlling the rise and fall times of the signals at nodes INP and INN, respectively.

The output stage 53 comprises an inverter formed by a second PMOS transistor M1 and a second NMOS transistor M2. The source of transistor M1 is connected to the supply voltage node VDD, while the source of transistor M2 is connected to ground. The drains of transistors M1 and M2 are connected together to form the output node O/P.

The gate of transistor M1 is connected to node INP, which is the node between transistor M3 and current source I1. Similarly, the gate of transistor M2 is connected to node INN, which is the node between transistor M4 and current source I2. This configuration allows for separate control of the turn-on times for transistors M1 and M2, which is used to reduce crowbar current.

The output node O/P is connected to the input of an output buffer 54. The output of buffer 54 forms the circuit output OUT1. A load capacitance CLOAD is shown connected between OUT1 and ground, representing the capacitive load of subsequent stages.

Turning to FIG. 5, a timing diagram is presented to illustrate the operation of the circuit in FIG. 4. The diagram shows the relative timing of signals at nodes IN1, INN, and INP.

When the signal at node IN1 transitions from low to high, transistor M4 turns on, quickly pulling node INN low and turning off transistor M2. Simultaneously, transistor M3 begins to turn off, but the discharge of node INP is deliberately slowed by current source I1. This controlled discharge creates a delay in turning on transistor M1, effectively preventing crowbar current in the stack of transistors M1-M2. The reverse process occurs when the signal at node IN1 transitions from high to low: transistor M3 starts to turn on, quickly pulling node INP high while transistor M4 turns off, allowing node INN to rise slowly due to current source I2. This controlled rise delays the turn-on of transistor M2. In both transitions, the circuit ensures that one transistor in the stack of transistors M1-M2 turns off before the other turns on, eliminating crowbar current and enhancing power efficiency. The output stage 54 sharpens the transitions at output O/P and represents the capacitive load of the driven circuit.

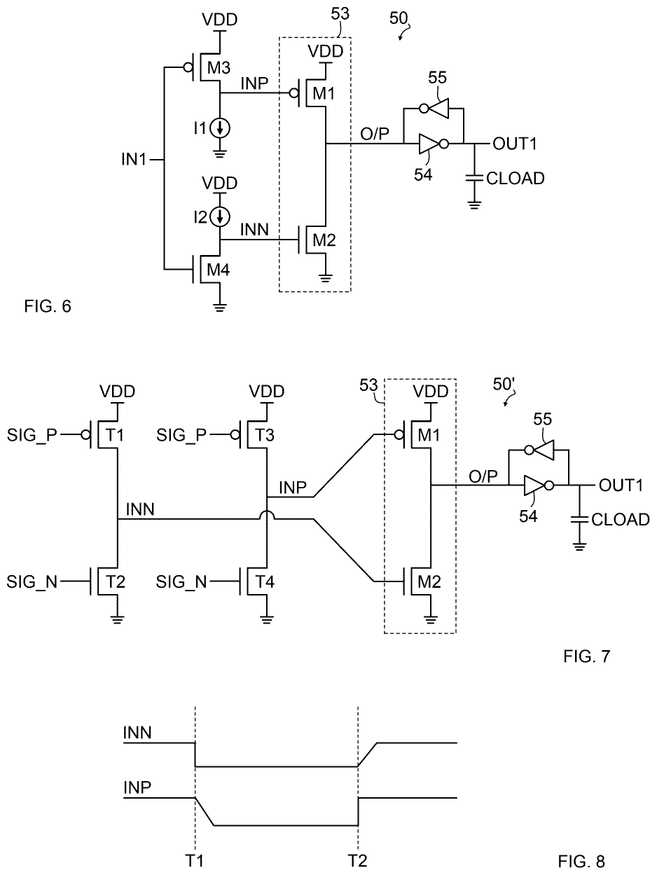

FIG. 6 shows an alternative embodiment of the circuit, labeled as reference 50. This embodiment builds upon the design shown in FIG. 4, with an addition to the output stage. Specifically, a current starved inverter 55 is added, in a feedback connection, forming a latch configuration with the output buffer 54.

The current starved inverter 55 mitigates the floating node situation that can occur when both the transistors M1 and M2 in the main inverter are off. This scenario can happen during the brief transition periods when neither transistor M1 nor transistor M2 is actively driving the output node.

The latch configuration formed by buffer 54 and current starved inverter 55 provides several advantages. For example, it prevents the output node from floating when both transistor M1 and transistor M2 are off, providing for a defined logic state at all times. Additionally, the current starved nature of inverter 55 limits the amount of current that can flow through the latch, which helps maintain the power efficiency of the overall circuit. Moreover, it helps to sharpen the edges of the output signal, improving overall signal integrity. Still further, it provides additional, controlled drive strength for capacitive loads without significantly increasing power consumption. Also, it reduces sensitivity to noise on the output node O/P, enhancing the robustness of the circuit.

In both embodiments, the use of current sources I1 and I2 in the input stage, combined with the split-gate drive to transistor M1 and transistor M2 in the output stage, allows for precise control over the timing of the output transistors. This timing control is helpful for minimizing the duration when both output transistors are simultaneously conducting, thereby significantly reducing crowbar current and improving overall power efficiency of the inverter circuit.

The circuits described in FIG. 4 and FIG. 6 are particularly well-suited for use in clock distribution networks within large digital systems, where power efficiency and signal integrity are of utmost importance. By minimizing crowbar current, these circuits can operate efficiently across a wide range of supply voltages, making them ideal for use in modern, low-power digital designs. The addition of the current starved latch (with inverters 54 and 55) in FIG. 6 further enhances this design by addressing the potential issues during transistor switching transitions, resulting in a more robust and efficient inverter circuit suitable for low-power applications.

Finally, it is evident that modifications and variations can be made to what has been described and illustrated herein without departing from the scope of this disclosure. For example, refer now to FIG. 7 in which another embodiment is illustrated. This embodiment implements a skewed push-pull architecture for the buffer implementation, building upon the designs shown in FIGS. 4 and 6. The circuit 50′ comprises three stages: two push-pull input stages and an output stage, collectively forming a low-power inverter with reduced crowbar current.

The first push-pull stage includes PMOS transistor T1 and NMOS transistor T2. The source of transistor T1 is connected to the supply voltage node VDD, while the source of transistor T2 is connected to ground. The gates of transistors T1 and T2 are connected to nodes SIG_P and SIG_N respectively, which are inputs to this stage. The drains of transistors T1 and T2 are connected together, forming the node INN at which the INN signal for transistor M2 is produced. The second push-pull stage follows a similar structure, including PMOS transistor T3 and NMOS transistor T4. The source of transistor T3 is connected to the supply voltage node VDD, and the source of transistor T4 is connected to ground. The gates of transistors T3 and T4 are connected to nodes SIG_P and SIG_N respectively. The drains of transistors T3 and T4 are connected together, forming the node INP at which the INP signal for transistor M1 is produced.

The output stage 53 comprises PMOS transistor M1 and NMOS transistor M2. The source of transistor M1 is connected to supply voltage node VDD, while the source of transistor M2 is connected to ground. The gate of transistor M1 is connected to the node INP, and the gate of transistor M2 is connected to the node INN. The drains of transistors M1 and M2 are connected together to form the output node O/P. An output buffer 54 is connected to the O/P node, and a current starved inverter 55 is connected between the output of buffer 54 and the O/P node, forming a latch configuration. A load capacitance CLOAD is shown connected between the output and ground. The input signals at nodes SIG_P and SIG_N for the first two push-pull stages are already available from the core circuit. These signals are effectively level-shifted versions of the same input, equivalent to two versions of the signal at node IN1 in the previous embodiments but with different DC biases. In the push-pull stages, transistors T2 and T3 are designed to be stronger than their counterpart transistors T1 and T4. This results in transistor T2 providing low fall times for the signal at node INN and transistor T3 providing low rise times for the signal at node INP signal. The signals at nodes INN and INP, driving the third stage (output stage), cause non-overlapping transitions in transistors M1 and M2. This non-overlap reduces crowbar current in the output stage - this can be observed in the graph of FIG. 8, illustrating the reduction of short-circuit current due to non-overlapping transitions of the signals at nodes INN and INP.

Various embodiments and variants have been described. Those skilled in the art will understand that certain features of these embodiments can be combined and other variants.

While this invention has been described with reference to illustrative embodiments, this description is not intended to be construed in a limiting manner. Various modifications and combinations of the illustrative embodiments, as well as other embodiments of the invention, will be apparent to skilled persons in the field of the invention upon reference to the description and the figures. It is therefore intended that the appended claims encompass any such modifications or embodiments.

Finally, the practical implementation of the embodiments and variants described herein is within the capabilities of those skilled in the art based on the functional description provided hereinabove while falling within the scope of the invention as defined in the attached claims.

1. A low-power clock buffer circuit, comprising:
an input stage including:
a first PMOS transistor and a first NMOS transistor, each having a gate connected to receive an input signal;
a first current source connected to a drain of the first PMOS transistor; and
a second current source connected to a drain of the first NMOS transistor; and
an output stage including:
a second PMOS transistor having a gate connected to the drain of the first PMOS transistor; and
a second NMOS transistor having a gate connected to the drain of the first NMOS transistor, wherein currents output by the first and second current sources control timing of signals applied to the gates of the second PMOS and second NMOS transistors to reduce crowbar current in the output stage.

2. The circuit of claim 1, further comprising an output buffer connected to drains of the second PMOS transistor and second NMOS transistor.

3. The circuit of claim 2, further comprising a current-starved inverter connected in a feedback configuration with the output buffer to form a latch.

4. The circuit of claim 1, wherein the first current source is connected between the drain of the first PMOS transistor and ground, and wherein the second current source is connected between a supply voltage and the drain of the first NMOS transistor.

5. The circuit of claim 1, wherein the currents output by the first and second current sources control rise and fall times of signals at the drains of the first PMOS and first NMOS transistors, respectively.

6. The circuit of claim 1, wherein the input stage and output stage collectively form a low-power inverter with reduced crowbar current.

7. The circuit of claim 1, wherein the circuit is configured to operate efficiently across a range of supply voltages in a clock distribution network of a digital system.

8. A low-power clock buffer circuit, comprising:
a first push-pull stage including:
a first PMOS transistor and a first NMOS transistor, each having a gate connected to receive a respective input signal, wherein drains of the first PMOS transistor and the first NMOS transistor are connected to form a first output node;
a second push-pull stage including:
a second PMOS transistor and a second NMOS transistor, each having a gate connected to receive the respective input signal, wherein drains of the second PMOS transistor and the second NMOS transistor are connected to form a second output node; and
an output stage including:
a third PMOS transistor having a gate connected to the second output node; and
a third NMOS transistor having a gate connected to the first output node, wherein the first NMOS transistor and the second PMOS transistor are configured to be stronger than the first PMOS transistor and the second NMOS transistor, respectively, to control timing of signals at the first and second output nodes applied to the gates of the third PMOS and third NMOS transistors to reduce crowbar current in the output stage.

9. The circuit of claim 8, further comprising an output buffer connected to drains of the third PMOS transistor and third NMOS transistor.

10. The circuit of claim 9, further comprising a current-starved inverter connected in a feedback configuration with the output buffer to form a latch.

11. The circuit of claim 8, wherein the first and second push-pull stages control rise and fall times of signals at the first and second output nodes, respectively.

12. The circuit of claim 8, wherein the signals at the first and second output nodes cause non-overlapping transitions in the third PMOS transistor and the third NMOS transistor.

13. A method of operating a clock buffer circuit, the method comprising:
receiving an input signal at an input stage;
controlling a first current source to limit current flow through a first branch of the input stage;
controlling a second current source to limit current flow through a second branch of the input stage;
generating a first control signal at a first node between a first transistor and the first current source;
generating a second control signal at a second node between a second transistor and the second current source;
controlling a turn-on time of a third transistor in an output stage using the first control signal;
controlling a turn-on time of a fourth transistor in the output stage using the second control signal; and
generating an output signal at an output node formed by a connection between the third and fourth transistors.

14. The method of claim 13, further comprising:
buffering the output signal using an output buffer; and
latching the buffered output signal using a current starved inverter connected between an output of the output buffer and the output node.

15. The method of claim 13, wherein controlling the turn-on times of the third and fourth transistors comprises causing one of the third or fourth transistors to turn off before the other turns on, thereby reducing crowbar current in the output stage.

16. The method of claim 13, further comprising: transitioning the input signal from a low state to a high state; in response to the low-to-high transition: quickly pulling the second control signal low to turn off the fourth transistor; and slowly discharging the first node to delay turning on the third transistor.

17. The method of claim 13, further comprising: transitioning the input signal from a high state to a low state; in response to the high-to-low transition: quickly pulling the first control signal high to turn off the third transistor; and slowly charging the second node to delay turning on the fourth transistor.

18. The method of claim 13, wherein the current starved inverter mitigates a floating node condition at the output node when both the third and fourth transistors are off.

19. The method of claim 13, wherein the current starved inverter limits the amount of current that can flow through a latch formed by the output buffer and the current starved inverter.

20. The method of claim 13, further comprising sharpening edges of the output signal using the combination of the output buffer and the current starved inverter.

21. The method of claim 13, further comprising reducing sensitivity to noise on the output node using the current starved inverter.

22. A method of operating a clock buffer circuit, the method comprising:
receiving respective input signals at a first push-pull stage and a second push-pull stage, the respective input signals being level-shifted versions of a common input signal;
generating a first control signal at a first output node of the first push-pull stage by driving a first PMOS transistor and a first NMOS transistor using the respective input signals;
generating a second control signal at a second output node of the second push-pull stage by driving a second PMOS transistor and a second NMOS transistor using the respective input signals;
controlling relative strengths of the first and second push-pull stages such that a stronger NMOS transistor in the first push-pull stage and a stronger PMOS transistor in the second push-pull stage produce non-overlapping transitions of the first and second control signals;
controlling a turn-on time of a third NMOS transistor in an output stage using the first control signal;
controlling a turn-on time of a third PMOS transistor in the output stage using the second control signal; and
generating an output signal at an output node formed by a connection between the third PMOS transistor and the third NMOS transistor..

23. The method of claim 22, further comprising:
buffering the output signal using an output buffer; and
latching the buffered output signal using a current-starved inverter connected between an output of the output buffer and the output node.

24. The method of claim 22, wherein controlling the turn-on times of the third PMOS and third NMOS transistors comprises causing the transistors to switch with non-overlapping transitions, thereby reducing crowbar current in the output stage.

25. The method of claim 22, further comprising: transitioning the common input signal from a low state to a high state; and in response to the low-to-high transition: quickly pulling the first control signal low to turn off the third NMOS transistor; and slowly raising the second control signal to delay turning on the third PMOS transistor.

26. The method of claim 22, further comprising: transitioning the common input signal from a high state to a low state; and in response to the high-to-low transition: quickly pulling the second control signal high to turn off the third PMOS transistor; and slowly lowering the first control signal to delay turning on the third NMOS transistor.

27. The method of claim 22, wherein the respective input signals applied to the first and second push-pull stages are differential or level-shifted versions of a common clock signal.

28. The method of claim 22, wherein the current-starved inverter mitigates a floating-node condition at the output node when both the third PMOS and the third NMOS transistors are off.

29. The method of claim 22, wherein the current-starved inverter limits an amount of current flowing through a latch formed by the output buffer and the current-starved inverter.

30. The method of claim 22, further comprising sharpening edges of the output signal and reducing sensitivity to noise on the output node using the latch formed by the output buffer and the current-starved inverter.
